(19) United States
(12) Patent Application Publication
(10) Pub. No.: US 2022/0010204 A1
(43) Pub. Date: Jan. 13, 2022

(54) SURFACE MODIFICATION METHOD FOR FLUORIDE LUMINESCENT MATERIAL AND FLUORIDE LUMINESCENT MATERIAL PREPARED THEREFROM

(71) Applicant: XIAMEN INSTITUTE OF RARE-EARTH MATERIALS, Xiamen, Fujian (CN)

(72) Inventors: Haomiao ZHU, Xiamen, Fujian (CN); Decai HUANG, Xiamen, Fujian (CN)

(21) Appl. No.: 17/293,824

(22) PCT Filed: Oct. 17, 2019
(86) PCT No.: PCT/CN2019/111737

§ 371 Date: May 13, 2021

(30) Foreign Application Priority Data
Nov. 13, 2018 (CN) 201811348987.0

(51) Int. Cl. C09K 11/67; C09K 11/02; C09K 11/64; C09K 11/66; C01G 45/06

(52) U.S. Cl. CPC C09K 11/675; C09K 11/025; H01L 29/22; C09K 11/665; C01G 45/06; C09K 11/645

(57) ABSTRACT

In a surface modification method for fluoride luminescent materials, an inorganic coating layer AₓMF_{y} coated substrate AₓMF_{y}:Mn⁴⁺ is mixed with an organic solution containing a metal phosphate, an alkoxysilane, an organic carboxylic acid or an organic amine. The solution is evaporated to give the organic-inorganic coating layer coated surface-modified fluoride luminescent material. The phosphor photoluminescence intensity and quantum efficiency of the modified phosphors can be maintained at 85%-95% under high temperature and high humidity conditions. After being coated with the inorganic coating layer, the surface defects of the phosphor are reduced, and the photoluminescence intensity and quantum yield of the phosphor are increased by 5%-15%. After being coated with the organic coating layer, the photoluminescence intensity of the phosphor is reduced <3%.

### CROSS-REFERENCE TO RELATED APPLICATIONS

The present application is a U.S. national entry of PCT international application serial number No. PCT/CN2019/111737, filed Oct. 17, 2019, which claims the priority of Chinese patent application 2018113489870 filed on Nov. 13, 2018 with China National Intellectual Property Administration, titled “SURFACE MODIFICATION METHOD FOR FLUORIDE LUMINESCENT MATERIAL AND FLUORIDE LUMINESCENT MATERIAL PREPARED THEREFROM”, which is incorporated herein by reference in its entirety.

### TECHNICAL FIELD

The present invention relates to the technical field of rare earth luminescent material and illumination display, in particular to a surface modification method for fluoride luminescent materials and a fluoride luminescent material prepared therefrom.

### BACKGROUND

As a new type of solid-state light source, white LED has advantages such as environmental protection, energy saving, high efficiency, and fast response compared with traditional light sources such as incandescent lamps and fluorescent lamps. It is honored as the fourth generation of green light source following incandescent lamps, fluorescent lamps and high-pressure gas discharge lamps. In the LED light source, the performance of phosphor determines the LED luminous efficiency, color rendering index, color temperature and service life and other technical indicators. Therefore, the phosphor plays an important role in white LED and is widely concerned. At present, the most commonly used method is to combine a blue LED chip (emitting wavelength at 440-480 nm) with a yellow phosphor (such as YAG:Ce or TAG:Ce). After the combination, the yellow phosphor absorbs the blue light from the blue LED chip to emit a yellow light, which mixes with an unabsorbed blue light to form a white light. However, in this way, only a cold white light device with a correlated color temperature (CCT) greater than 4500 K and a lower color rendering index less than 80 can be obtained. The main reason lies in the lack of red light in the emission spectrum of commonly used yellow phosphors, which makes it difficult to obtain a white LED device with low color temperature and high color rendering index, the keys to the indoor application of the white LED. In order to achieve this goal, an effective way is to add an appropriate amount of red phosphors to a white LED device to enhance the red emission of the device.

Mn⁴⁺-activated fluoride phosphors have a narrow emission peak with a small half-peak width, and are the hotspots in the research of red light-emitting materials. The patent application US2009/7497973 disclosed a Mn⁴⁺-activated A₂MF₆ (A is K, Na, Rb, etc.; M is Ti, Si, Sn, Ge, etc.) red phosphor, which is obtained by dissolving the starting material in hydrofluoric acid at a high concentration and then heating the volatile cocrystal. The patent application WO2009/119486 disclosed a fluoride product, which is obtained by dissolving elemental Si in a solution of hydrofluoric acid and potassium permanganate. The patent application CN102732249A disclosed a fluoride product, which is obtained by mixing the first solution containing the fluoride of metal M with the second solution containing A or the compound of A in a solid form, and reating to give the precipitate. The fluoride luminescent materials prepared by those methods have the advantages of high photoluminescence efficiency and good thermal stability. However, none of those methods have overcome the shortcoming of easy hydrolysis of fluoride luminescent materials. Therefore, the fluoride luminescent materials are easy to be hydrolyzed in long-term use or under a humid condition, leading to the decrease of photoluminescence efficiency or even failure. The patent application US2007/0125984A1 reported a method for improving the humidity resistance of a phosphor by coating a layer of inorganic material (such as TiO₂, Al₂O₃, and SiO₂) on the surface of the phosphor as a protective film. However, such an aqueous phase coating technique is difficult to apply to the coating of fluoride phosphors. Similarly, the patent application CN106479485A disclosed a method for improving the high temperature and high humidity resistance of a phosphor by coating a layer of potassium silicate-sodium hydroxymethylcellulose-polyethylene glycol mixture on the surface of the phosphor. However, such an organic coating material has the disadvantages of high temperature intolerance and easy decomposition, which affects the efficiency of long-term use of phosphors. Therefore, it is of great practical significance to improve the humidity resistance of fluoride phosphors while prolonging the service life of white LED, which meets the requirements of energy saving and environmental protection.

### SUMMARY

Mn⁴⁺-doped fluoride red phosphor is easy to hydrolyze under a humid condition due to its poor humidity resistance, which leads to the decrease of efficiency or even failure of the red phosphor and the reduction of the service life of LED. In order to improve the humidity resistance of the fluoride red phosphor, it is necessary to perform the surface modification for phosphor material by coating an inorganic thin layer or an organic thin layer on the surface of phosphor material to form a protective layer with humidity resistance.

In order to overcome the shortcomings of the prior art, the present invention is intended to provide a surface modification method for fluoride luminescent materials and a fluoride luminescent material prepared therefrom. In the present invention, Mn⁴⁺ on the surface of a substrate AₓMF_{y}:Mn⁴⁺ is removed by ion exchange to form a structure of an inorganic coating layer AₓMF_{y} coated substrate AₓMF_{y}:Mn⁴⁺, which is denoted as AₓMF_{y}:Mn⁴⁺@AₓMF_{y}. The AₓMF_{y}:Mn⁴⁺@AₓMF_{y} can effectively prevent the luminescence center inside the substrate AₓMF_{y}:Mn⁴⁺ from transferring energy to the surface to avoid the resulting fluorescence quenching and improve the photoluminescence efficiency of the fluoride luminescent material. Then an organic coating layer is coated on the outer surface of the inorganic coating layer to form a hydrophobic layer, so as to effectively improve the stability of fluoride luminescent materials under high temperature and high humidity conditions without significantly reducing the photoluminescence efficiency of fluoride luminescent materials. The method features simple preparation process, wide source of starting materials and low consumption of hydrofluoric acid, which is suitable for large-scale industrial preparation.

The purpose of the present invention can be achieved through the following technical solutions:

A surface-modified fluoride luminescent material comprising a substrate, an inorganic coating layer and an organic coating layer, the inorganic coating layer being coated on the outer surface of the substrate, and the organic coating layer being coated on the outer surface of the inorganic coating layer; wherein

the substrate is AₓMF_{y}:Mn⁴⁺, and the inorganic coating layer is AₓMF_{y}; wherein A is selected from one of alkali metals Li, Na, K, Rb and Cs, and a combination thereof; M is selected from one of Ti, Si, Ge, Sn, Zr, Al, Bi, Ga and In, and a combination thereof; x is an absolute value of the charge of [MF_{y}] ion; y is 4, 5, 6 or 7; and Mn⁴⁺ is a luminescence center ion.

According to an embodiment of the present invention, preferably, x is an absolute value of the charge of [MF₆] ion, and y is 6.

According to an embodiment of the present invention, preferably, the inorganic coating layer AₓMF_{y} is obtained by removing Mn⁴⁺ on the surface layer of the substrate AₓMF_{y}:Mn⁴⁺ by ion exchange.

According to an embodiment of the present invention, in the surface-modified fluoride luminescent material, the inorganic coating layer can be a single layer or multiple layers, and the organic coating layer coated on the outer surface of the inorganic coating layer can also be a single layer or multiple layers. As an example, a double-layer coating structure is that a single inorganic coating layer is coated on the surface of a substrate, and an organic coating layer is coated on the outer surface of the single inorganic coating layer. A multi-layer coating structure can be that multiple inorganic coating layers are coated on the surface of a substrate, and a single organic coating layer is coated on the outer surface of the multiple inorganic layers; or that a single inorganic coating layer is coated on the surface of a substrate, and multiple organic coating layers are coated on the outer surface of the single inorganic coating layer; or that multiple inorganic coating layers are coated on the surface of a substrate, and multiple organic coatings are coated on the outer surface of the multiple inorganic coating layers.

The multiple organic coating layers are the same or different in composition, and preferably, the adjacent organic coating layers are different in composition.

According to an embodiment of the present invention, the inorganic coating layer and the organic coating layer are bonded by a chemical bond.

According to an embodiment of the present invention, the organic coating layer is at least one of metal phosphates, alkoxysilanes, organic carboxylic acids and organic amines.

According to an embodiment of the present invention, the phosphate in the metal phosphate is phosphomonoester or phosphodiester, for example, P(O)(OH)₂(OR) or P(O)(OH)(OR)₂, wherein R is hydrocarbyl, for example, alkyl (such as a C₁₋₂₀ alkyl).

According to an embodiment of the present invention, the phosphate is obtained by esterifying a phosphorus source with an alcohol, wherein the phosphorus source is selected from one of P₂O₅ and POCl₃, and a combination thereof, and the alcohol is at least one selected from methanol, ethanol, n-propanol, isopropanol, n-butanol, and isobutanol.

According to an embodiment of the present invention, the metal in the metal phosphate is a metal cation; for example, the metal in the metal phosphate is selected from one of Al, Ti, Si, Ga and Zn ions, and a combination thereof.

According to an embodiment of the present invention, the alkoxysilane is Si(OR¹)₃(R²), wherein R¹ is C₁₋₆ alkyl, and R² is C₁₋₂₀ alkyl or C₁₋₂₀ alkenyl; for example, the alkoxysilane is selected from methyl trimethoxysilane, ethyl trimethoxysilane, n-propyl trimethoxysilane, n-octyl trimethoxysilane, ethenyl trimethoxysilane, dodecyl trimethoxysilane, hexadecyl trimethoxysilane, and octadecyl trimethoxysilane.

According to an embodiment of the present invention, the organic carboxylic acid is R³COOH, wherein R³ is C₁₋₃₀ alkyl; for example, the organic carboxylic acid is selected from oleic acid, stearic acid, docosanoic acid, octacosanoic acid, and lauric acid.

According to an embodiment of the present invention, the organic amine is NR⁴(R⁵)₂, wherein R⁴ is C₁₋₁₀ alkyl, and R⁵, which may be the same or different, is H or C₁₋₁₀ alkyl; for example, the organic amine is selected from methylamine, ethylamine, propylamine, butylamine, octylamine, and hexylamine, and the corresponding secondary amine or tertiary amine. The corresponding one is the secondary amine or tertiary amine of methylamine, ethylamine, propylamine, butylamine, octylamine, and hexylamine.

The present invention also provides a preparation method for the surface-modified fluoride luminescent material, comprising the following steps:

(1) dissolving the compound AₓMF_{y} in hydrofluoric acid solution to form a saturated solution;
(2) adding the substrate AₓMF_{y}:Mn⁴⁺ into the saturated solution in step (1), and obtaining an inorganic coating layer AₓMF_{y} coated substrate AₓMF_{y}:Mn⁴⁺ by ion exchange reaction, which is denoted as AₓMF_{y}:Mn⁴⁺@AₓMF_{y};
(3) preparing an organic solution;
(4) mixing the inorganic coating layer AₓMF_{y} coated substrate AₓMF_{y}:Mn⁴⁺ in step (2) with the organic solution in step (3), and heating and stirring the mixture until the organic solvent is removed, to give the surface-modified fluoride luminescent material, which is denoted as AₓMF_{y}:Mn⁴⁺@AₓMF_{y}@organic layer;
wherein A is selected from one of alkali metals Li, Na, K, Rb and Cs, and a combination thereof; M is selected from one of Ti, Si, Ge, Sn, Zr, Al, Bi, Ga and In, and a combination thereof; x is an absolute value of the charge of [MF_{y}] ion; y is 4, 5, 6 or 7; and Mn⁴⁺ is a luminescence center ion.

According to an embodiment of the present invention, in step (1), the mass percentage of hydrofluoric acid in the hydrofluoric acid solution is 20%-50%.

According to an embodiment of the present invention, in step (1), the saturated solution is preferably formed at 20-90° C.

According to an embodiment of the present invention, in step (2), the mass ratio of the substrate AₓMF_{y}:Mn⁴⁺ to the compound AₓMF_{y} in the saturated solution in step (1) is 10:1-1:5, and preferably, 1:1.

According to an embodiment of the present invention, in step (2), the ion exchange process is performed at 0-100° C., and preferably, at 25-80° C.

According to an embodiment of the present invention, in step (2), the ion exchange is performed for at least 30 s, for example, for at least 1 min, and preferably, for at least 5 min.

According to an embodiment of the present invention, in step (2), the ion exchange is performed under a continuous stirring condition.

According to an embodiment of the present invention, step (2) further comprises the following step: filtering and drying the mixture after the ion exchange is completed.

According to an embodiment of the present invention, in step (3), the organic solution is at least one of metal phosphate solution, alkoxysilane solution, organic carboxylic acid solution and organic amine solution, and the preparation process for the solution is, for example:

dissolving an alkoxysilane, an organic carboxylic acid or an organic amine in an organic solvent, wherein the organic solvent is at least one of methanol, ethanol, propanol, n-hexane, and cyclohexane; or
mixing a metal source and a phosphorus source with an alcohol for a reaction to give a metal phosphate solution, wherein the phosphorus source is selected from one of P₂O₅ and POCl₃, and a combination thereof; the alcohol is at least one of methanol, ethanol, n-propanol, isopropanol, n-butanol, and isobutanol; and the metal source is metal nitrate, metal sulfate or metal oxalate, or one or more of metal organic salts such as isopropoxide, ethoxide, propoxide or butoxide.

According to an embodiment of the present invention, in step (3), the content of the alkoxysilane, the organic carboxylic acid or the organic amine in the organic solvent is at least 1 wt. %, and preferably, 5 wt. %.

According to the embodiment of the present invention, preferably, the metal source is Al(NO₃)₃.9H₂O, Zn(NO₃)₂.6H₂O, titanium butoxide, or aluminum isopropoxide.

According to an embodiment of the present invention, in the organic solution containing the metal phosphate, the mass percentage of the metal source is at least 0.1%, and the mass percentage of the phosphorus source is at least 10%.

According to an embodiment of the present invention, in step (4), the temperature of the heating and stirring is at least 30° C., and preferably, at least 50° C.

According to an embodiment of the present invention, in step (4), the mass ratio of the inorganic coating layer AₓMF_{y} coated substrate AₓMF_{y}:Mn⁴⁺ to the organic solution is 5:1-1:20, and preferably, 1:1-1:5.

According to an embodiment of the present invention, step (4) further comprises the following step: washing with an alcohol solution or acetone, and drying.

According to an embodiment of the present invention, in step (2), preferably, the AₓMF_{y}:Mn⁴⁺ is selected from A₂MF₆:Mn⁴⁺ and A₃MF₆:Mn⁴⁺, wherein the A₂MF₆:Mn⁴⁺ is selected from K₂TiF₆:Mn⁴⁺, K₂SiF₆:Mn⁴⁺, Na₂SiF₆:Mn⁴⁺, Na₂TiF₆:Mn⁴⁺, K₂GeF₆:Mn⁴⁺, Na₂SnF₆:Mn⁴⁺, Cs₂TiF₆:Mn⁴⁺ and Cs₂SiF₆:Mn⁴⁺, and preferably, the A₂MF₆:Mn⁴⁺ is selected from K₂TiF₆:Mn⁴⁺, K₂SiF₆:Mn⁴⁺ and K₂GeF₆:Mn⁴⁺.

Preferably, the A₃MF₆:Mn⁴⁺ is selected from Na₃AlF₆:Mn⁴⁺, K₃AlF₆:Mn⁴⁺, Li₃AlF₆:Mn⁴⁺, Rb₃AlF₆:Mn⁴⁺, Cs₃AlF₆:Mn⁴⁺, K₂NaAlF₆:Mn⁴⁺ and K₂LiAlF₆:Mn⁴⁺, and more preferably, the A₃MF₆:Mn⁴⁺ is selected from Na₃AlF₆:Mn⁴⁺, K₃AlF₆:Mn⁴⁺ and K₂NaAlF₆:Mn⁴⁺.

According to an embodiment of the present invention, in step (1), preferably, the AₓMF_{y} is selected from A₂MF₆ and A₃MF₆, wherein the A₂MF₆ is selected from K₂TiF₆, K₂SiF₆, Na₂SiF₆, Na₂TiF₆, K₂GeF₆, Na₂SnF₆, Cs₂TiF₆ and Cs₂SiF₆, and more preferably, the A₂MF₆ is selected from K₂TiF₆, K₂SiF₆ and K₂GeF₆.

Preferably, the A₃MF₆ is selected from Na₃AlF₆, K₃AlF₆, Li₃AlF₆, Rb₃AlF₆, Cs₃AlF₆, K₂NaAlF₆ and K₂LiAlF₆, and more preferably, the A₃MF₆ is selected from Na₃AlF₆, K₃AlF₆ and K₂NaAlF₆.

According to an embodiment of the present invention, in steps (2) and (4), the filtered product can be further washed with an organic solvent such as absolute ethanol or acetone to remove the residual acid on the surface, and dried.

In the present invention, when mixing a substrate AₓMF_{y}:Mn⁴⁺ with a saturated solution of a compound AₓMF_{y} in hydrofluoric acid, the Mn⁴⁺ on the surface layer of the substrate AₓMF_{y}:Mn⁴⁺ is reacted with the metal cation M in the saturated hydrofluoric acid solution of the compound AₓMF_{y} for ion exchange, so that surface layer of the substrate AₓMF_{y}:Mn⁴⁺ is free of Me, and a core-shell structure of the inorganic coating layer AₓMF_{y} coated substrate AₓMF_{y}:Mn⁴⁺ is formed, with the particle size of the substrate AₓMF_{y}:Mn⁴⁺ not changed. The prepared intermediate can effectively prevent the internal luminescence center of the phosphor from transferring energy to the quenching center on the surface due to its surface layer without Me, thereby improving the photoluminescence efficiency of the phosphor. However, the outer surface of the inorganic coating layer coated phosphor has a limited thickness and insufficient water resistance.

In the present invention, an inorganic coating layer AₓMF_{y} coated substrate AₓMF_{y}:Mn⁴⁺ is mixed with an organic solution containing a metal phosphate, an alkoxysilane, an organic carboxylic acid or an organic amine. Then the organic solution is evaporated to give the organic-inorganic coating layer coated substrate AₓMF_{y}:Mn⁴⁺ (i.e., the surface-modified fluoride luminescent material). Since the surface-modified fluoride luminescent material has no excitation center Mn⁴⁺ at the interface between the inorganic coating layer and the organic coating layer, the luminescence performance of the phosphor is less reduced.

### Beneficial Effects:

(1) The surface-modified Mn⁴⁺-doped fluoride luminescent material of the present invention has a coating structure with an inorganic layer and an organic layer that significantly improves the corrosion resistance of the fluoride phosphor. The modified phosphor has photoluminescence intensity and quantum efficiency retention rate up to 85%-95% under high temperature and high humidity conditions, and can be widely used in the field of white LED backlight display.

(2) The inorganic coating layer in the present invention has the same composition as the phosphor substrate, and can be one or more layers. After the phosphor is coated with the inorganic coating layer, its surface defects are reduced, and its photoluminescence intensity and quantum yield are increased by 5%-15%.

(3) The organic coating layer in the present invention avoids being directly coated on the surface of the substrate A₂MF₆:Mn⁴⁺ phosphor, which prevents the direct contact between the organic coating layer and Mn⁴⁺, thereby reducing the photoluminescence intensity and quantum yield of the material. The organic layer can be one or more layers. After the phosphor is coated with the organic coating layer, its photoluminescence intensity is reduced by only less than 3%. It can be seen that the modified material of the present invention not only improves the corrosion and humidity resistance of the material, but also maintains the luminescence performance of the fluoride luminescent material.

(4) The surface modification method provided herein has the advantages of low preparation temperature, short time, and easy process control, which is suitable for large-scale industrial preparation. In addition, the surface modification method provided herein has a wide range of application, and therefore can be used for the surface modification of similar phosphors with poor humidity resistance.

### BRIEF DESCRIPTION OF THE DRAWINGS

FIG. 1 shows the XRD diffraction pattern of the K₂TiF₆:Mn⁴⁺@K₂TiF₆@metal phosphate phosphor in (C) of Example 1 of the present invention.

FIG. 2 shows the XRD diffraction pattern of the K₂SiF₆:Mn⁴⁺@K₂SiF₆@metal phosphate phosphor in (C) of Example 2 of the present invention.

FIG. 3 shows the XRD diffraction pattern of the K₂GeF₆:Mn⁴⁺@K₂GeF₆@metal phosphate phosphor in (C) of Example 3 of the present invention.

FIG. 4 shows the scanning electron micrograph of the K₂TiF₆:Mn⁴⁺ phosphor in (A) of Example 1 of the present invention.

FIG. 5 shows the scanning electron micrograph of the K₂TiF₆:Mn⁴⁺@K₂TiF₆ phosphor in (B) of Example 1 of the present invention.

FIG. 6 shows the scanning electron micrograph of the K₂TiF₆:Mn⁴⁺@K₂TiF₆@metal phosphate phosphor in (C) of Example 1 of the present invention.

FIG. 7 shows the changes in photoluminescence intensity of the sample encapsulated with the phosphors in Example 1 and Preparation Example 1 of the present invention and with silica gel after aging at 85° C. and 85% humidity.

FIG. 8 shows the changes in photoluminescence intensity of the sample encapsulated with the phosphors in Example 2 and Preparation Example 2 of the present invention and with silica gel after aging at 85° C. and 85% humidity.

FIG. 9 shows the changes in photoluminescence intensity of the sample encapsulated with the phosphors in Example 3 and Preparation Example 3 of the present invention and with silica gel after aging at 85° C. and 85% humidity.

FIG. 10 is a schematic diagram of the structure of the surface-modified phosphor according to a preferred embodiment of the present invention.

### DETAILED DESCRIPTION

The preparation method of the present invention will be further illustrated in detail with reference to the following specific examples. It should be understood that the following examples are merely exemplary illustration and explanation of the present invention, and should not be construed as limiting the scope of protection of the present invention. All techniques implemented based on the aforementioned contents of the present invention are encompassed within the scope of protection of the present invention.

Unless otherwise stated, the experimental methods used in the following examples are conventional methods. Unless otherwise stated, the reagents, materials, and the like used in the following examples are commercially available.

### Instruments and Equipment

An X-ray powder diffractometer (DMAX 2500PC, Rigaku) was used for phase analysis; a field emission scanning electron microscopy (FE-SEM, Hitachi SU1510) was used to observe the sample morphology; and an FLS980 (Edinburgh Instrument) fluorescence spectrometer was used to characterize the fluorescence spectra of the samples.

The fluoride phosphor in the specific example of the present invention had a chemical general formula of A₂MF₆:Mn⁴⁺, wherein A was selected from one of alkali metals Li, Na, K, Rb and Cs, and a combination thereof; M was selected from one of Ti, Si, Ge, Sn, Zr, Al, Bi, Ga and In, and a combination thereof; and Mn⁴⁺ was a luminescence center ion. The preparation process is as follows: an oxide, a salt or an acid containing M was dissolved in a 20%-50% HF solution according to the formula stoichiometric ratio of the Mn⁴⁺-doped fluoride phosphor material, and then the fluoride of A was added; after being stirred for 1-10 min, the mixture was added with A₂MnF₆, stirred for 30-90 min, then left to stand, and filtered; and the resulting precipitate was washed, and dried to give the fluoride red phosphor A₂MF₆.

### Preparation Examples 1-3: Preparation of A₂MF₆:Mn⁴⁺ Phosphor

The synthesis methods of Preparation Examples 1-3 were the same, except for differences in the type and amount of starting materials. The specific parameters are shown in Table 1 below. The specific process was illustrated by taking the K₂MF₆:Mn⁴⁺ phosphor of Preparation Example 1 as an example: K₂MnF₆ was dissolved in a hydrofluoric acid solution; after being stirred for 1-10 min, the solution was added with the A₂MF₆ powder, stirred at room temperature for 30-90 min, and filtered; and the resulting precipitate was washed with acetone to remove the residual HF completely, dried in an oven at 70° C. for 4 h to give the final phosphor. The excitation and emission spectra, fluorescence quantum yield and absorption efficiency of the product were measured by an FLS980 (Edinburgh Instrument) fluorescence spectrometer. The results are shown in Table 2.

TABLE 1
Synthesis technical parameters of Preparation Examples 1-3

| | | | | | | HF |
|---|---|---|---|---|---|---|
| Preparation | | | | | | concen- |
| Example | Starting material | | | Reaction time | | tration |
| Preparation | K₂TiF₆ | 2.5 g | K₂MnF₆ | 0.18 g | 30 min | 49% |
| Example 1 | | | | | | |
| Preparation | K₂SiF₆ | 2.5 g | K₂MnF₆ | 0.10 g | 90 min | 49% |
| Example 2 | | | | | | |
| Preparation | K₂GeF₆ | 2.5 g | K₂MnF₆ | 0.12 g | 60 min | 49% |
| Example 3 | | | | | | |

### Example 1

(A) Preparation of Modified K₂TiF₆:Mn⁴⁺@K₂TiF₆ Phosphor

Compound K₂TiF₆ was added to a 49% HF solution (10 mL) until it was no longer dissolved. The solution was filtered to remove the undissolved K₂TiF₆ to give a saturated solution of K₂TiF₆ in the 49% HF solution. Then the saturated solution was added to a container containing the K₂TiF₆:Mn⁴⁺ phosphor (1 g) obtained in Preparation Example 1. The solution was stirred at room temperature for 30 min, filtered under vacuum, washed with acetone 3 times to remove the residual HF, and dried in an oven at 70° C. for 4 h to give the inorganic coating layer K₂TiF₆ coated substrate K₂TiF₆:Mn⁴⁺, which was denoted as K₂TiF₆:Mn⁴⁺@K₂TiF₆ phosphor. The excitation and emission spectra and internal fluorescence quantum yield of the product were measured by an FLS980 fluorescence spectrometer. The important luminescence performance parameters of the prepared phosphor are shown in Table 2.

(B) Preparation of Modified K₂TiF₆:Mn⁴⁺@Metal Phosphate Phosphor

P₂O₅ (0.0350 g) was added to an ethanol solution (10 mL). The solution was stirred continuously, and added with Al(NO₃)₃.9H₂O (0.1468 g) with a molar ratio of 1:1 of Al:P. Then the solution was heated to 70° C. while stirring, added with the K₂TiF₆:Mn⁴⁺ phosphor (1 g) in Preparation Example 1, heated and stirred until the solution was evaporated to dryness. The residue was washed with acetone several times, dried in an oven at 140° C. for 4 h to give a phosphor, which was denoted as K₂TiF₆:Mn⁴⁺@metal phosphate phosphor. The important luminescence performance parameters of the prepared phosphor are shown in Table 2.

(C) Preparation of Modified K₂TiF₆:Me@K₂TiF₆@Metal Phosphate Phosphor

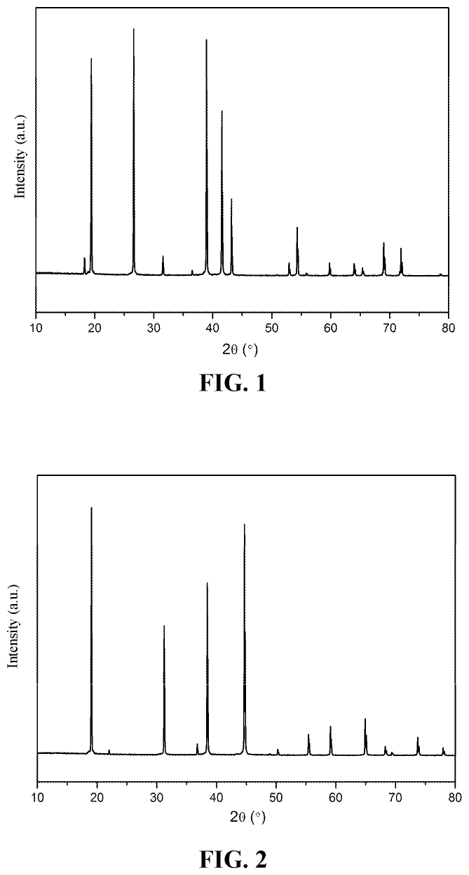

P₂O₅ (0.0350 g) was added to an ethanol solution (10 mL). The solution was stirred continuously, and added with Al(NO₃)₃.9H₂O (0.1468 g) with a molar ratio of 1:1 of Al:P. Then the solution was heated to 70° C. while stirring, added with the K₂TiF₆:Me@K₂TiF₆ phosphor (1 g) prepared in (A) of Example 1, heated and stirred until the solution was evaporated to dryness. The residue was washed with acetone several times, dried in an oven at 140° C. for 4 h to give a phosphor, which was denoted as K₂TiF₆:Me@K₂TiF₆@metal phosphate phosphor. The X-ray powder diffraction shows that the product is still pure-phase K₂TiF₆ (FIG. 1), and no other impurity phases are introduced. The important luminescence performance parameters of the prepared phosphor are shown in Table 2.

(D) Preparation of Modified K₂TiF₆:Me@K₂TiF₆@Octadecyl Trimethoxysilane Phosphor

Octadecyl trimethoxysilane (2.5 mL) was added to n-hexane (50 mL). The solution was stirred for 30 min, and added with the K₂TiF₆:Me@K₂TiF₆ phosphor (1 g) prepared in (A) of Example 1. Then the solution was heated to 70° C. and stirred until the solution was evaporated to dryness. The residue was washed with n-hexane several times, dried in an oven at 150° C. for 4 h to give a phosphor, which was denoted as K₂TiF₆:Me@K₂TiF₆@octadecyl trimethoxysilane phosphor. The important luminescence performance parameters of the prepared phosphor are shown in Table 2.

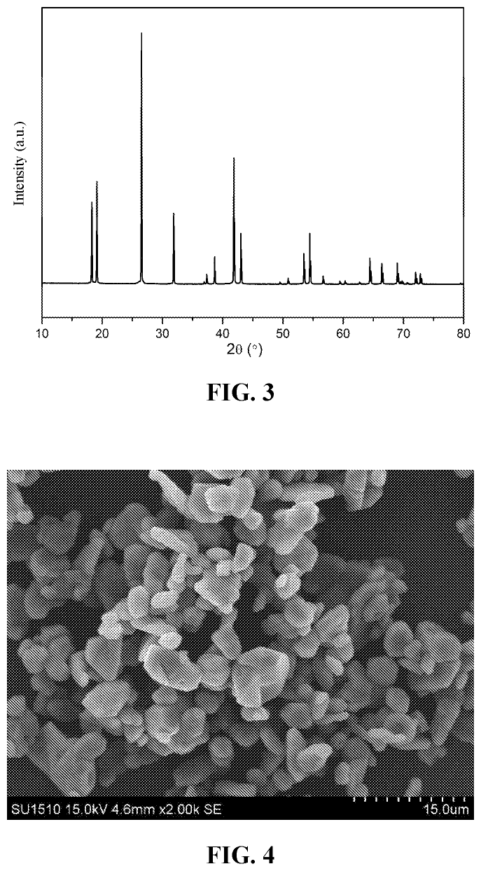

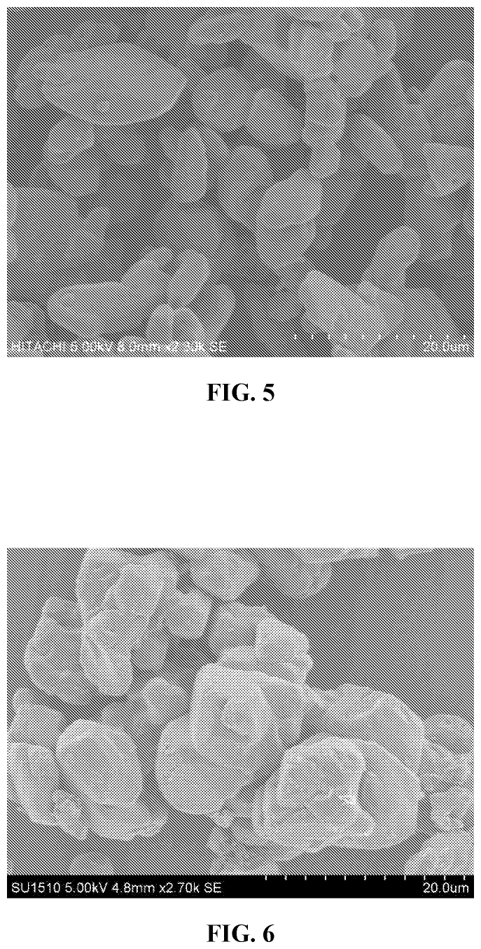

FIGS. 4-6 are the scanning electron micrographs of the phosphors prepared in (A), (B) and (C) of Example 1. It can be seen from those figures that the inorganic coating layer coated sample has a smooth surface and an unchanged particle size, and the organic coating layer coated sample has a small amount of fine substances on the surface.

### Example 2

(A) Preparation of Modified K₂SiF₆:Me@K₂SiF₆ Phosphor

Compound K₂SiF₆ was added to a 49% HF solution (10 mL) until it was no longer dissolved. The solution was filtered to remove the undissolved K₂SiF₆ to give a saturated solution of K₂SiF₆ in the 49% HF solution. Then the saturated solution was added to a container containing the K₂SiF₆:Mn⁴⁺ phosphor (1 g) obtained in Preparation Example 2. The solution was stirred at room temperature for 30 min with an ethanol being added dropwise at 0.5 mL/min. Then the solution was filtered under vacuum, washed with acetone 3 times to remove the residual HF, and dried in an oven at 70° C. for 4 h to give the K₂SiF₆:Me@K₂SiF₆ phosphor. The excitation and emission spectra and internal fluorescence quantum yield of the product were measured by an FLS980 fluorescence spectrometer. The important luminescence performance parameters of the prepared phosphor are shown in Table 2.

(B) Preparation of Modified K₂SiF₆:Me@Metal Phosphate Phosphor

P₂O₅ (0.0350 g) was added to an ethanol solution (10 mL). The solution was stirred continuously, and added with Al(NO₃)₃.9H₂O (0.1468 g) with a molar ratio of 1:1 of Al:P. Then the solution was heated to 70° C. while stirring, added with the K₂SiF₆:Mn⁴⁺ phosphor (1 g) in Preparation Example 2, heated and stirred until the solution was evaporated to dryness. The residue was washed with acetone several times, dried in an oven at 140° C. for 4 h to give a phosphor. The important luminescence performance parameters of the prepared phosphor are shown in Table 2.

(C) Preparation of Modified K₂SiF₆:Me@K₂SiF₆@Metal Phosphate Phosphor

P₂O₅ (0.0350 g) was added to an ethanol solution (10 mL). The solution was stirred continuously, and added with Al(NO₃)₃.9H₂O (0.1468 g) with a molar ratio of 1:1 of Al:P. Then the solution was heated to 70° C. while stirring, added with the K₂SiF₆:Me@K₂SiF₆ phosphor (1 g) prepared in (A) of Example 2, heated and stirred until the solution was evaporated to dryness. The residue was washed with acetone several times, dried in an oven at 140° C. for 4 h to give a phosphor. The X-ray powder diffraction shows that the product is still pure-phase K₂SiF₆ (FIG. 2), and no other impurity phases are introduced. The important luminescence performance parameters of the prepared phosphor are shown in Table 2.

(D) Preparation of Modified K₂SiF₆:Me@K₂SiF₆@Hexadecyl Trimethoxysilane Phosphor

Hexadecyl trimethoxysilane (5 mL) was added to n-hexane (50 mL). The solution was stirred for 30 min, and added with the K₂SiF₆:Me@K₂SiF₆ phosphor (1 g) prepared in (A) of Example 2. Then the solution was heated to 70° C. and stirred until the solution was evaporated to dryness. The residue was washed with n-hexane several times, dried in an oven at 150° C. for 4 h to give a phosphor, which was denoted as K₂SiF₆:Me@K₂SiF₆@hexadecyl trimethoxysilane phosphor. The important luminescence performance parameters of the prepared phosphor are shown in Table 2.

### Example 3

(A) Preparation of Modified K₂GeF₆:Me@K₂GeF₆ Phosphor

Compound K₂GeF₆ was added to a 49% HF solution (10 mL) until it was no longer dissolved. The solution was filtered to remove the undissolved K₂GeF₆ to give a saturated solution of K₂GeF₆ in the 49% HF solution. Then the saturated solution was added to a container containing the K₂GeF₆:Mn⁴⁺ phosphor obtained in Preparation Example 3. The solution was stirred at room temperature for 30 min with an ethanol being added dropwise at 0.5 mL/min. Then the solution was filtered under vacuum, washed with acetone 3 times to remove the residual HF, and dried in an oven at 70° C. for 4 h to give the K₂GeF₆:Me@K₂GeF₆ phosphor. The excitation and emission spectra and internal fluorescence quantum yield of the product were measured by an FLS980 fluorescence spectrometer. The important luminescence performance parameters of the prepared phosphor are shown in Table 2.

(B) Preparation of Modified K₂GeF₆:Me@Metal Phosphate Phosphor

P₂O₅ (0.0350 g) was added to an ethanol solution (10 mL). The solution was stirred continuously, and added with Al(NO₃)₃.9H₂O (0.1468 g) with a molar ratio of 1:1 of Al:P. Then the solution was heated to 70° C. while stirring, added with the K₂GeF₆:Mn⁴⁺ phosphor (1 g) in Preparation Example 3, heated and stirred until the solution was evaporated to dryness. The residue was washed with acetone several times, dried in an oven at 140° C. for 4 h to give a phosphor. The important luminescence performance parameters of the prepared phosphor are shown in Table 2.

(C) Preparation of Modified K₂GeF₆:Me@K₂GeF₆@Metal Phosphate Phosphor

P₂O₅ (0.0350 g) was added to an ethanol solution (10 mL). The solution was stirred continuously, and added with Al(NO₃)₃.9H₂O (0.1468 g) with a molar ratio of 1:1 of Al:P. Then the solution was heated to 70° C. while stirring, added with the K₂GeF₆:Mn⁴⁺@K₂GeF₆ phosphor (1 g) prepared in (A) of Example 3, heated and stirred until the solution was evaporated to dryness. The residue was washed with acetone several times, dried in an oven at 140° C. for 4 h to give a phosphor. The X-ray powder diffraction shows that the product is still pure-phase K₂GeF₆ (FIG. 3), and no other impurity phases are introduced. The important luminescence performance parameters of the prepared phosphor are shown in Table 2.

(D) Preparation of Modified K₂GeF₆:Mn⁴⁺@K₂GeF₆@Dodecyl Trimethoxysilane Phosphor

Dodecyl trimethoxysilane (5 mL) was added to n-hexane (50 mL). The solution was stirred for 30 min, and added with the K₂GeF₆:Mn⁴⁺@K₂GeF₆ phosphor (1 g) prepared in (A) of Example 3. Then the solution was heated to 70° C. and stirred until the solution was evaporated to dryness. The residue was washed with n-hexane several times, dried in an oven at 150° C. for 4 h to give a phosphor, which was denoted as K₂GeF₆:Mn⁴⁺@K₂GeF₆@dodecyl trimethoxysilane phosphor. The important luminescence performance parameters of the prepared phosphor are shown in Table 2.

TABLE 2
Luminescence performance parameters of aged samples

| | | Quantum | | Relative |
|---|---|---|---|---|
| System | Example | yield | AbsorptanceAbsorptance | luminance |
| K₂TiF₆:Mn⁴⁺ | Preparation | 93% | 71% | 94% |
| | Example 1 | | | |
| | Example 1 (A) | 98% | 68% | 100% |
| | Example 1 (B) | 85% | 60% | 88% |
| | Example 1 (C) | 94% | 67% | 95% |
| | Example 1 (D) | 93% | 65% | 94% |
| K₂SiF₆:Mn⁴⁺ | Preparation | 91% | 64% | 91% |
| | Example 2 | | | |
| | Example 2 (A) | 96% | 62% | 100% |
| | Example 2 (B) | 84% | 56% | 85% |
| | Example 2 (C) | 93% | 61% | 93% |
| | Example 2 (D) | 92% | 60% | 92% |
| K₂GeF₆:Mn⁴⁺ | Preparation | 89% | 58% | 92% |
| | Example 3 | | | |
| | Example 3 (A) | 94% | 56% | 100% |
| | Example 3 (B) | 81% | 52% | 86% |
| | Example 3 (C) | 91% | 55% | 94% |
| | Example 3 (D) | 90% | 54% | 91% |

It can be seen from Table 2 that an inorganic coating layer coated phosphor has increased quantum yield and luminance but a slightly decreased absorptance; an organic coating layer coated phosphor has significantly decreased luminance and quantum yield; and an inorganic-organic coating layer coated phosphor has a basically unchanged or slightly increased quantum yield as compared to an uncoated phosphor.

### Example 4. Stability Test

Each of the phosphor samples (0.1 g) prepared in Preparation Examples 1-3 and Examples 1-3 was mixed well with silica gel (A and B), encapsulated in a customized polytetrafluoroethylene mold, defoamed and hardened to give phosphor films. The films were aged in a programmable temperature & humidity chamber at 85° C. and 85% relative humidity. The spectrum and quantum efficiency of the samples were measured every 24 h to evaluate the high temperature and high humidity stability of the phosphors.

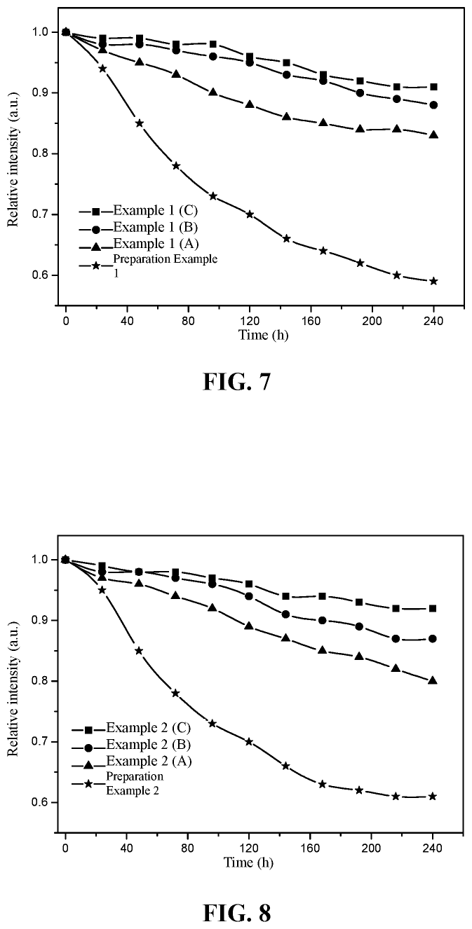

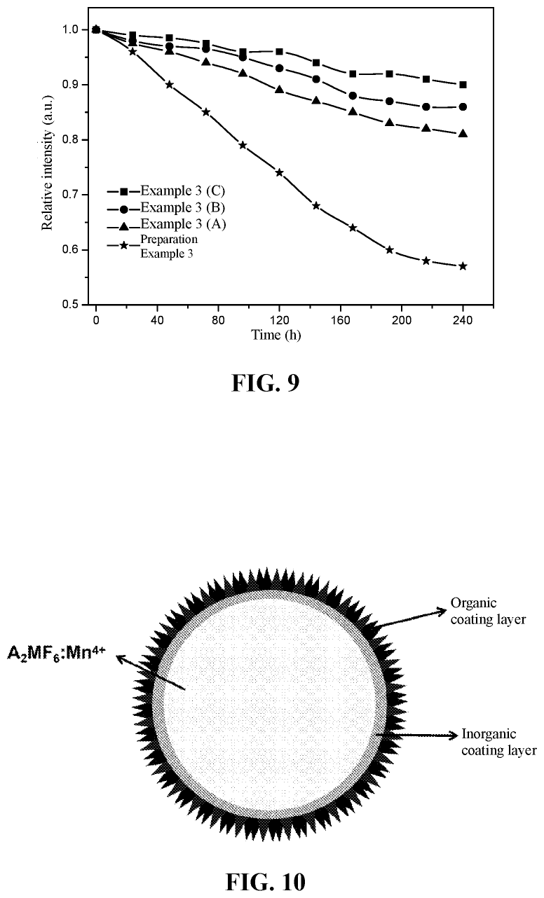

FIGS. 7, 8 and 9 show the changes in photoluminescence intensity of the above phosphors after aging at 85° C. and 85% relative humidity. It can be seen from FIG. 7 that the humidity resistance of the inorganic-organic coating layer coated phosphor disclosed herein has been greatly improved. After 240 h, the photoluminescence intensity of the phosphor prepared in (C) of Example 1 still maintains 92%. The photoluminescence intensity of the inorganic coating layer coated fluoride phosphor ((A) of Example 1) is only 83%, and the photoluminescence intensity of the fluoride phosphor without surface modification (prepared in Preparation Example 1) is only 59%. It can be seen that the inorganic-organic layer coating achieves a more excellent effect compared with the organic layer coating or the inorganic layer coating. The aging test results of other examples and preparation examples are similar (see FIG. 8 and FIG. 9).

The examples of the present invention have been described above. However, the present invention is not limited to the above examples. Any modification, equivalent, improvement and the like made without departing from the spirit and principle of the present invention shall fall within the protection scope of the present invention.

1. A surface-modified fluoride luminescent material, wherein the luminescent material comprises a substrate, an inorganic coating layer and an organic coating layer, the inorganic coating layer being coated on the outer surface of the substrate, and the organic coating layer being coated on the outer surface of the inorganic coating layer; wherein
the substrate is AₓMF_{y}:Mn⁴⁺, and the inorganic coating layer is AₓMF_{y}; wherein A is selected from one of alkali metals Li, Na, K, Rb and Cs and a combination thereof; M is selected from one of Ti, Si, Ge, Sn, Zr, Al, Bi, Ga and In, and a combination thereof; x is an absolute value of the charge of [MF_{y}] ion; y is 4, 5, 6 or 7; and Mn⁴⁺ is a luminescence center ion.

2. The surface-modified fluoride luminescent material according to claim 1, wherein x is an absolute value of the charge of [MF₆] ion, and y is 6.

3. The surface-modified fluoride luminescent material according to claim 1, wherein the inorganic coating layer can be a single layer or multiple layers, and the organic coating layer coated on the outer surface of the inorganic coating layer can also be a single layer or multiple layers.

4. The surface-modified fluoride luminescent material according to claim 1, wherein the organic coating layer is at least one of metal phosphate, alkoxysilane, organic carboxylic acid and organic amine.

5. The surface-modified fluoride luminescent material according to claim 1, wherein the phosphate in the metal phosphate is phosphomonoester or phosphodiester, such as P(O)(OH)₂(OR) or P(O)(OH)(OR)₂, wherein R is hydrocarbyl; preferably, the phosphate is obtained by esterifying a phosphorus source with an alcohol,
wherein the phosphorus source is selected from one of P₂O₅ and POCl₃, or a combination thereof; and the alcohol is at least one selected from methanol, ethanol, n-propanol, isopropanol, n-butanol and isobutanol;
preferably, the metal in the metal phosphate is selected from one of Al, Ti, Si, Ga and Zn ions, and a combination thereof;
preferably, the alkoxysilane is Si(OR¹)₃(R²), wherein R¹ is C₁₋₆ alkyl, and R² is C₁₋₂₀ alkyl or C₁₋₂₀ alkenyl; for example, the alkoxysilane is selected from methyl trimethoxysilane, ethyl trimethoxysilane, n-propyl trimethoxysilane, n-octyl trimethoxysilane, ethenyl trimethoxysilane, dodecyl trimethoxysilane, hexadecyl trimethoxysilane, and octadecyl trimethoxysilane;
preferably, the organic carboxylic acid is R³COOH, wherein R³ is C₁₋₃₀ alkyl; for example, the organic carboxylic acid is selected from oleic acid, stearic acid, docosanoic acid, octacosanoic acid, and lauric acid;
preferably, the organic amine is NR⁴(R⁵)₂, wherein R⁴ is C₁₋₁₀ alkyl, and R⁵, which may be the same or different, is H or C₁₋₁₀ alkyl; for example, the organic amine is selected from methylamine, ethylamine, propylamine, butylamine, octylamine, and hexylamine, and the corresponding secondary amine or tertiary amine.

6. A preparation method for the surface-modified fluoride luminescent material according to claim 1, comprising the following steps:
(1) dissolving the compound AₓMF_{y} in hydrofluoric acid solution to form a saturated solution;
(2) adding the substrate AₓMF_{y}:Mn⁴⁺ into the saturated solution in step (1), and obtaining an substrate AₓMF_{y}:Mn⁴⁺ coated with inorganic coating layer AₓMF_{y} by ion exchange reaction, which is denoted as AₓMF_{y}:Mn⁴⁺@AₓMF_{y};
(3) preparing an organic solution;
(4) mixing the substrate AₓMF_{y}:Mn⁴⁺ coated with inorganic coating layer AₓMF_{y} obtained in step (2) with the organic solution in step (3), and heating and stirring the mixture until the organic solvent is removed, to give the surface-modified fluoride luminescent material, which is denoted as AₓMF_{y}:Mn⁴⁺@AₓMF_{y} organic layer;
wherein A is selected from one of alkali metals Li, Na, K, Rb and Cs, or a combination thereof;
M is selected from one of Ti, Si, Ge, Sn, Zr, Al, Bi, Ga and In, or a combination thereof; x is an absolute value of the charge of [MF_{y}] ion; y is 4, 5, 6 or 7; and Mn⁴⁺ is a luminescence center ion.

7. The preparation method according to claim 6, wherein in step (2), the mass ratio of the substrate AₓMF_{y}:Mn⁴⁺ to the compound AₓMF_{y} in the saturated solution in step (1) is 10:1-1:5, and preferably, 1:1;
preferably, in step (2), the ion exchange process is performed at 0-100° C., and preferably, at 25-80° C.

8. The preparation method according to claim 6, wherein in step (3), the organic solution is at least one of a metal phosphate solution, an alkoxysilane solution, an organic carboxylic acid solution and an organic amine solution, and the preparation process for the solution is, for example:
dissolving an alkoxysilane, an organic carboxylic acid or an organic amine in an organic solvent, wherein the organic solvent is at least one selected from methanol, ethanol, propanol, n-hexane, and cyclohexane;
mixing a metal source and a phosphorus source with an alcohol for esterification to give a metal phosphate solution, wherein the phosphorus source is selected from one of P₂O₅ and POCl₃, or a combination thereof; the alcohol is at least one selected from methanol, ethanol, n-propanol, isopropanol, n-butanol, and isobutanol; and the metal source is metal nitrate, metal sulfate or metal oxalate, or one or more of metal organic salts such as isopropoxide, ethoxide, propoxide or butoxide, and preferably, the metal source is Al(NO₃)₃.9H₂O, Zn(NO₃)₂.6H₂O, titanium butoxide, or aluminum isopropoxide.

9. The preparation method according to claim 6,
wherein in step (4), the temperature of the heating and stirring is at least 30° C., and preferably, at least 50° C.;
preferably, in step (4), the mass ratio of the substrate AₓMF_{y}:Mn⁴⁺ coated with inorganic coating layer AₓMF_{y} to the organic solution is 5:1-1:20, and preferably, 1:1-1:5.

10. The method according to claim 6, wherein in step (2), the AₓMF_{y}:Mn⁴⁺ is selected from A₂MF₆:Mn⁴⁺ and A₃MF₆:Mn⁴⁺, wherein
the A₂MF₆:Mn⁴⁺ is selected from K₂TiF₆:Mn⁴⁺, K₂SiF₆:Mn⁴⁺, Na₂SiF₆:Mn⁴⁺, Na₂TiF₆:Mn⁴⁺, K₂GeF₆:Mn⁴⁺, Na₂SnF₆:Mn⁴⁺, Cs₂TiF₆:Mn⁴⁺ and Cs₂SiF₆:Mn⁴⁺; and
the A₃MF₆:Mn⁴⁺ is selected from Na₃AlF₆:Me, K₃AlF₆:Mn⁴⁺, Li₃AlF₆:Mn⁴⁺, Rb₃AlF₆:Mn⁴⁺, Cs₃AlF₆:Mn⁴⁺, K₂NaAlF₆:Mn⁴⁺ and K₂LiAlF₆:Mn⁴⁺; and
preferably, in step (1), the AₓMF_{y} is selected from A₂MF 6 and A₃MF₆, wherein
the A₂MF₆ is selected from K₂TiF₆, K₂SiF₆, Na₂SiF₆, Na₂TiF₆, K₂GeF₆, Na₂SnF₆, Cs₂TiF₆ and Cs₂SiF₆; and
the A₃MF₆ is selected from Na₃AlF₆, K₃AlF₆, Li₃AlF₆, Rb₃AlF₆, Cs₃AlF₆, K₂NaAlF₆ and K₂LiAlF₆.
